(19) United States
(12) Patent Application Publication
(10) Pub. No.: US 2016/0203989 A1
(43) Pub. Date: Jul. 14, 2016

(54) LOCAL DRY ETCHING APPARATUS AND LOCAL DRY ETCHING FABRICATION METHOD

(71) Applicant: SPEEDFAM CO., LTD., Kanagawa (JP)

(72) Inventor: Yasushi OBARA, Ayase-Shi (JP)

(73) Assignee: SPEEDFAM Co., Ltd., Ayase-shi (JP)

(21) Appl. No.: 14/916,524

(22) PCT Filed: Sep. 4, 2014
(86) PCT No.: PCT/JP2014/073323

§ 371 Date: Mar. 3, 2016

(30) Foreign Application Priority Data
Sep. 9, 2013 (JP) 2013-186694

(51) Int. Cl. H01L 21/3065; H01J 37/32; H01L 21/66

(52) U.S. Cl. CPC H01L 21/3065; H01L 22/12; H01L 22/20; H01J 37/32192; H01J 37/3244; H01J 2237/334

(57) ABSTRACT

A local dry etching apparatus includes a vacuum chamber, a single workpiece table, a plurality of discharge tubes, a raw material gas supply device for supplying a raw material gas to a selected discharge tube, a single electromagnetic wave oscillator capable of output adjustment, and waveguides provided with an electromagnetic wave switcher. A discharge tube selected from the plurality of discharge tubes to be irradiated with the electromagnetic wave is switched sequentially by the electromagnetic wave switcher.

### CROSS-REFERENCE TO RELATED APPLICATIONS

This application is a national phase filing under 35 U.S.C. §371 of International Application No. PCT/JP2014/073323, filed Sep. 4, 2014, and which claims priority to Japanese Patent Application No. 2013-186694, filed on Sep. 9, 2013, the contents of which prior applications are incorporated herein by reference.

### FIELD OF THE INVENTION

The present invention relates to a local etching apparatus. A fabrication method referred to as local etching fabrication is a technique of locally etching the surface of a workpiece such as a silicon wafer or a semiconductor wafer with an active species gas, thereby flattening the surface or making the thickness distribution uniform.

### BACKGROUND OF THE INVENTION

FIG. 1 is an explanatory view for explaining the principle of a method of flattening a workpiece by local dry etching using plasma. An active species gas G in plasma generated by a plasma generating portion A that constitutes a portion of a discharge tube B is injected from a nozzle N to the surface of a workpiece W. The workpiece W is mounted and fixed on a workpiece table T, and the workpiece table T is scanned at a speed and a pitch controlled in a horizontal direction relative to the nozzle N.

The workpiece W varies in thickness according to position and has fine unevenness before flattening fabrication. Before dry etching for flattening, the thickness in each sectioned area of the workpiece W is measured. This measurement provides data on the thickness at a position in each area, that is, position-thickness data.

In the local dry etching fabrication, a removed amount of a material in each area corresponds to a time during which the area is exposed to the active species gas G. Therefore, the relative speed of the nozzle passing by the workpiece (hereinafter referred to as “nozzle speed”) is determined such that the nozzle moves relatively slowly over a relatively thick portion (hereinafter referred to as a relatively thick portion) Wa and relatively fast over a relatively thin portion.

FIG. 2 is a graph showing a distribution of a removed amount (depth) of a workpiece material per unit time with an injected active species gas, that is, an etching rate. This curve called etching rate profile is very similar to a Gaussian distribution curve. As shown in FIG. 2, the etching rate E has a maximum value Emax at the center line of the nozzle N and decreases as the distance from the center in the direction of radius r increases.

Thus, since the material removing capability shows a distribution according to the distance from the center of the nozzle, the removed amount of the material required for one area cannot be determined by consideration only about the nozzle speed of one area. That is, even though the material has been removed in one area, when a neighborhood area such as an adjacent area or a further adjacent area is to be etched, the material is removed in overlapped manner in accordance with the etching rate profile.

Thus, since one area is influenced by the etching of all neighborhood areas, the nozzle speed is calculated so that the surface heights of all the areas become identical to each other as a result of overlapping these influences of all the areas (refer to Patent Literature 1, 6, and 7).

The local dry etching fabrication is greatly different from common dry etching (refer to Patent Literature 2 to 5), in that the nozzle is caused to scan under such a controlled speed.

### CITATION LIST

PTL 1: JP-A No. 2002-252210

PTL 2: JP-A No. H11(1999)-135485

PTL 3: JP-A No. 2004-047559

PTL 4: JP-A No. H03(1991)-039480

PTL 5: JP-A No. H11(1999)-087094

PTL 6: JP-A No. 2004-128079

PTL 7: JP-A No. 2004-134661

### SUMMARY OF THE INVENTION

A desired surface shape should be obtained when local dry etching is performed at a nozzle speed obtained by calculation based on the position-thickness (or unevenness) data and the etching rate profile. However, when the discharge tube is used continuously, degradation C such as gradual deposition of reaction products, erosion or modification on the inner surface of the discharge tube occurs by the reaction of the active species gas formed in the discharge tube with the inner surface of the discharge tube, and thus, before a reaction of an electromagnetic wave with the raw material gas, a loss of the electromagnetic wave is caused by a reaction of the electromagnetic wave with the inner surface of the discharge tube by the degradation C, which lowers a fabrication performance.

When the fabrication performance is lowered, that is, the etching rate profile is lowered, unevenness after fabrication is no more within a predetermined allowable range. Accordingly, it is necessary to tune the local dry etching apparatus such that the result of fabrication is within the predetermined range by increasing the output of the electromagnetic wave oscillator to maintain the etching rate profile.

Then, when the fabrication performance is further lowered continuously, the discharge tube can no more withstand further use. Accordingly, the discharge tube has to be replaced. Since the replacement of the discharge tube requires such a large scale operation that, for example, breaking a vacuum of a vacuum chamber is required before the discharge tube replacement and evacuation of the chamber is required again after the replacement, this takes much time which is not comparable with that for the tuning.

Further, in local dry etching to a silicon wafer or a semiconductor wafer requiring high accuracy, even fine variations of a plasma state may greatly fluctuate the result of fabrication since the material removal amount (stock removal amount) of the workpiece by fabrication is extremely small (about several tens to hundreds nanometer range). For performing severe fabrication of removing fine unevenness on the workpiece surface by local dry etching, it is also important to control and stabilize the state of the discharge tube together with maintenance of the fabrication accuracy by the tuning.

The present invention has been achieved in view of the foregoing situations and it has subjects in the local dry etching apparatus to minimize the number of times of tuning, to fabricate as long as possible by the identical tuning, and to minimize the number of times of breaking a vacuum of the vacuum chamber to atmospheric pressure for the replacement of the discharge tube, that is, to minimize the number of times of evacuation, thereby improving the entire fabrication efficiency in the local dry etching fabrication, and further suppressing the fluctuation of fabrication conditions caused by degradation of the discharge tube by inhibiting progress of the degradation of the discharge tube, and further performing fabrication at high accuracy while maintaining a stable fabrication rate.

The subjects described above are solved by the following means. That is, a first aspect of the invention provides a local dry etching apparatus including: a vacuum chamber, a plurality of discharge tubes each having a nozzle opening in the vacuum chamber at the downstream side for injecting an active species gas converted into plasma, a single workpiece table which mounts a workpiece thereon and is disposed in the vacuum chamber to the injection destination of the active species gas from the nozzle, a control device for controlling planar movement of the workpiece table, a raw material gas supply device for supplying a raw material gas as the raw material for the active species gas to a discharge tube selected from the plurality of the discharge tubes, a single electromagnetic wave oscillator capable of output adjustment, plasma generation portions each forming a part of the plurality of the discharge tubes where the raw material gas is converted into plasma to form an active species gas by irradiation of an electromagnetic wave oscillated by the single electromagnetic wave oscillator, and an electromagnetic wave transmission unit comprising an electromagnetic wave switcher for switching the path of the electromagnetic wave in order to irradiate the electromagnetic wave oscillated by the single electromagnetic wave oscillator to the plasma generation portion of the discharge tube selected from the plurality of the discharge tubes for the supply of the raw material gas.

A second aspect of the invention provides the local dry etching apparatus according to the first local dry etching apparatus in which the raw material gas supply device is switched by a valve device incidental to the local dry etching apparatus so as to supply the gas from a single raw material gas supply source to a discharge tube selected from the plurality of the discharge tubes.

A third aspect of the invention provides a local dry etching fabrication method using the local dry etching apparatus of the first or the second invention, the method including: subjecting a workpiece to local dry etching fabrication by the local dry etching apparatus; then measuring the unloaded workpiece after fabrication; calculating an etching rate during fabrication based on the result of the measurement; and then fabricating the next workpiece by using the same discharge tube at the identical output as it was when the calculated etching rate is within an allowable range not requiring adjustment of the output of the electromagnetic wave oscillator, or switching the irradiation of the electromagnetic wave by the electromagnetic wave switcher and switching the supply of the raw material gas in order to use another discharge tube not used for the fabrication described above when the etching rate is out of the allowable range; and further repeating the local dry etching fabrication by adjusting the output of the electromagnetic wave oscillator to a higher output when all of the plurality of the discharge tubes have been used at the identical output of the electromagnetic wave oscillator as it has been; thereby reducing frequency of evacuation accompanied by replacement of the discharge tubes and frequency of tuning.

A fourth aspect of the invention provides the local dry etching fabrication method according to the third local dry etching fabrication method, in which the raw material gas supply device is switched by a valve device incidental to the local dry etching apparatus so as to supply a gas from a single raw material gas supply source to a discharge tube selected from the plurality of the discharge tubes.

According to the aspects of the present invention, a workpiece is subjected to dry etching fabrication, the unloaded workpiece after the fabrication is measured, and an etching rate during the fabrication is calculated based on the result of the measurement. And then the next workpiece is fabricated by using the same discharge tube at the identical output as it was when the calculated etching rate is within an allowable range not requiring output adjustment of the electromagnetic wave oscillator, or the irradiation of the electromagnetic wave is switched by the electromagnetic wave switcher and supply of the raw material gas is switched in order to use another discharge tube not used in the fabrication described above when the etching rate is out of the allowable range.

Then, when all of the plurality of discharge tubes have been used at the identical output of the electromagnetic wave oscillator as it has been, the output of the electromagnetic wave oscillator is adjusted to a higher output and then the local dry etching fabrication is repeated.

As a result, in the local dry etching apparatus since the number of times of tuning can be decreased or long time fabrication can be performed by the identical tuning, and the number of times of breaking vacuum of the vacuum chamber to atmospheric pressure for replacement of the discharge tube, that is, the number of times of evacuation can be decreased, this can provide advantageous effects capable of improving the entire fabrication efficiency in the local dry etching fabrication and, further, suppressing fluctuation of fabrication conditions caused by degradation of the discharge tube as much as possible by inhibiting the progress of degradation of the discharge tube, and capable of performing fabrication at a high accuracy while maintaining a stable fabrication rate.

### BRIEF DESCRIPTION OF THE DRAWINGS

FIG. 1 is an explanatory view for explaining the principle of a method of flattening a workpiece by local dry etching using plasma.

FIG. 2 is a graph illustrating a distribution of an etching rate of an injected active species gas.

FIG. 3 is an explanatory view illustrating an embodiment of a local dry etching apparatus according to the present invention.

FIG. 4 is an explanatory plan view illustrating FIG. 3.

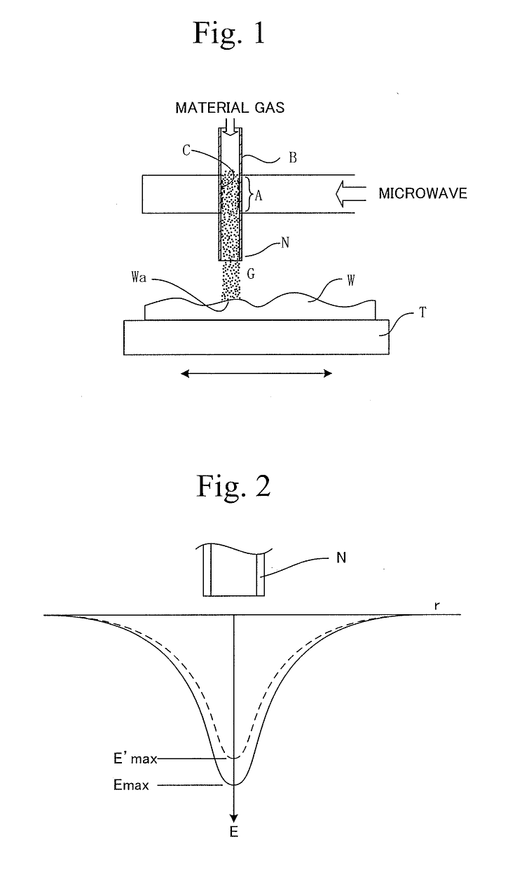

### DETAILED DESCRIPTION OF THE INVENTION

An embodiment of the present invention is to be described below with reference to the drawings.

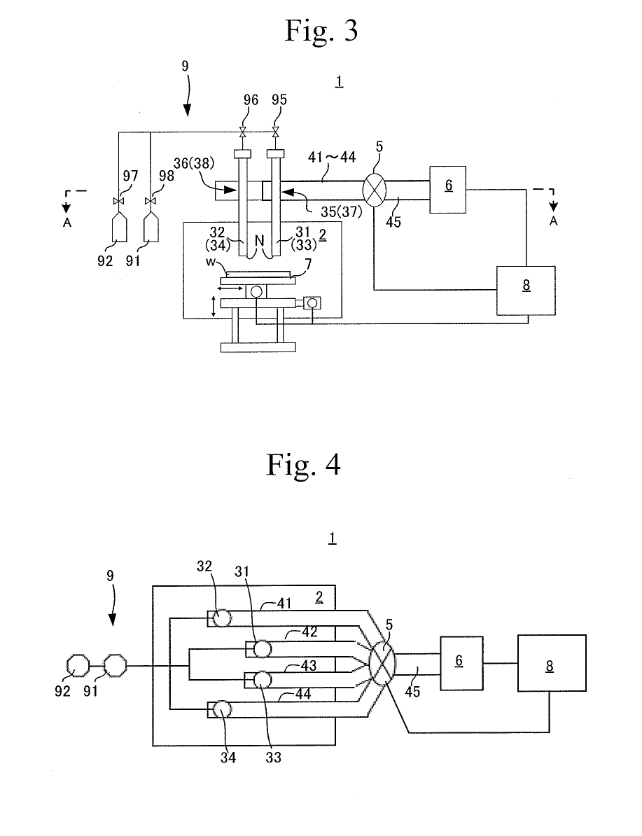

FIG. 3 is an explanatory view illustrating an example of a local dry etching apparatus according to the present invention. The local dry etching apparatus 1 of this embodiment includes a vacuum chamber 2, discharge tubes 31 to 34, waveguides 41 to 44, and 45 as an electromagnetic wave transmission unit, an electromagnetic wave switcher 5, an electromagnetic wave oscillator 6, a workpiece table 7, a control device 8, and a raw material gas supply device 9.

Each of the discharge tubes 31 to 34 has a nozzle N opening in the vacuum chamber 2 at the downstream side for injecting an active species gas converted into plasma. A plurality of discharge tubes 31 to 34 are provided to the single vacuum chamber 2. The workpiece table 7, on which a workpiece W is mounted and fixed, is disposed in the vacuum chamber 2 to an injection destination of the active species gas from the nozzle N. The workpiece table 7 is provided by one corresponding to the single vacuum chamber 2. The planar movement of the workpiece table 7 is controlled by the control device 8.

The raw material gas supply device 9 supplies a gas from cylinders 91 and 92 as a raw material gas supply source containing a raw material gas (including SF₆ (sulfur hexafluoride) gas) as the raw material for the active species gas to the upstream side of a discharge tube selected from the plurality of discharge tubes 31 to 34. For this purpose, switching valves 95 to 98 are provided.

Each of the plasma generation portions 35 to 38 forms a portion of each of the discharge tubes 31 to 34. An electromagnetic wave (including microwave) oscillated by the single electromagnetic wave oscillator 6 is irradiated, being selectively switched, to the plasma generation portions 35 to 38 of a discharge tube selected from the plurality of discharge tubes 31 to 34 for the supply of the raw material gas and the raw material gas is converted into plasma to form an active species gas. The output of the electromagnetic wave oscillator 6 can be adjusted.

As described above, the electromagnetic wave switcher 5 switches the path of the electromagnetic wave (including microwave) for irradiating the electromagnetic wave oscillated by the single electromagnetic wave oscillator 6 to the plasma generation portion of the discharge tube selected from the plurality of the discharge tubes 31 to 34 for the supply of the raw material gas. The electromagnetic wave switcher 5 is provided in a portion of the waveguides 41 to 45 as the electromagnetic transmission unit.

The control device 8 performs control in general, for example, of the electromagnetic wave oscillator 6 and the electromagnetic wave switcher 5 in addition to the control for the planar movement of the workpiece table 7 as described above. Although not shown, a load chamber and a transfer chamber are provided to the vacuum chamber 2. The load chamber is a small-volume chamber provided for facilitating the adjustment of pressure such that the pressure is made equal with that of the vacuum chamber 2 in advance when the workpiece W is put into and out of the vacuum chamber 2. The transfer chamber contains a transfer robot in the inside and the workpiece is transferred by the robot between the vacuum chamber 2 and the load chamber. Loading/unloading doors are provided between the chambers in a manner such that vacuum or atmospheric air does not move between the chambers.

The waveguides 41 to 44 are electromagnetic wave transmission channels for irradiating the electromagnetic wave (including microwave) oscillated by the electromagnetic wave oscillator 6 to a selected discharge tube, in which the electromagnetic wave (including microwave) oscillated in the electromagnetic wave oscillator 6 is transmitted through the waveguide 45, switched by the electromagnetic wave switcher 5 for the transmission destination of the electromagnetic wave, and introduced to one of the discharge tubes 31 to 34. The waveguides 4l to 44 are externally provided to the discharge tubes 31 to 34, respectively. While four discharge tubes are illustrated in this embodiment, two or more tubes may be used optionally. Numbers of the waveguide 41 to 44 and numbers of switching stages of the electromagnetic wave switcher 5 also correspond to them.

Each of the discharge tubes 31 to 34 is a cylindrical body having a nozzle N formed at the lower end and a supply pipe of the raw material gas supply device 9 is connected to the upper end. The raw material gas supply device 9 is a device for supplying the raw material gas into the discharge tubes 31 to 34, and has cylinders 91 and 92 for various kinds of raw material gases such as a SF₆ (sulfur hexafluoride) gas. And the cylinders 91 and 92 are connected to the discharge tubes 31 to 34 by way of the valves 95, 96, 97 and 98 disposed to the supply pipes. The SF₆ gas is an example of the raw material gas and, in addition, CF₄, NF₃ or the like can also be selected.

When the raw material gas is supplied from the raw material gas supply device 9 to one selected discharge tube 31 to 34 and the electromagnetic wave is oscillated by the electromagnetic wave oscillator 6, the raw material gas is converted into plasma in the selected discharge tube 31 to 34. The active species gas G formed by plasma conversion is injected from the nozzle N.

The workpiece W is disposed on the workpiece table 7 in the vacuum chamber 2, and attracted electrostatically to the workpiece table 7. A vacuum pump (not shown) is attached to the vacuum chamber 2 and the inside of the vacuum chamber 2 is evacuated (depressurized) by the vacuum pump.

The local dry etching apparatus operates as described below. In the initial state, it is assumed that the all of the discharge tubes 31 to 34 installed are new, the vacuum chamber 2 has been evacuated, and a workpiece W is loaded on the workpiece table 7.

Local dry etching fabrication is performed under fabrication conditions calculated based on the unevenness information of the workpiece W which has been acquired beforehand. The workpiece W is unloaded and the unloaded workpiece after fabrication is measured. Based on the result of the measurement, an etching rate during the actual fabrication is calculated. When the calculated etching rate does not require output adjustment of the electromagnetic wave oscillator 6, that is, when the etching rate during the actual fabrication is within an allowable range, the next workpiece is fabricated by using the same discharge tube at the identical output as it was.

Since the fabrication performance of the discharge tube lowers by repeating of the fabrication, the etching rate will become out of the allowable range. When it is out of the range, the discharge tube to be used is switched from the first discharge tube to the next discharge tube (that is, to another discharge tube not used in the fabrication described above). The switching is performed by switching the supply of the raw material gas by the valve device, and switching the irradiation of the electromagnetic wave by the electromagnetic wave switcher 5. What is important is that the electromagnetic wave oscillator 6 remains at the identical output as it was without tuning.

As the workpieces are fabricated successively, all of the plurality of discharge tubes (four tubes in total in this embodiment) are used up by the fabrication at the identical output of the electromagnetic wave oscillator. Here, the electromagnetic wave oscillator is tuned, that is, the output is adjusted to a higher output and the local dry etching fabrication is repeated. Since the performance of the discharge tube lowers as the fabrication is repeated to such a level that lowering cannot be coped with by the tuning, the discharge tube is replaced here.

The discharge tube cannot be replaced unless the vacuum in the vacuum chamber 2 is broken. Then, once vacuum is broken, the inside should be evacuated again after replacement of the discharge tube. When one discharge tube is used as the conventional case, the vacuum chamber 2 needs to have the vacuum broken and to be evacuated by the same number of times for one discharge tube.

On the contrary, in the present invention, since the vacuum chamber 2 needs to have the vacuum broken and to be evacuated for the next fabrication only for once when the life time of the plurality of discharge tubes (four tubes in this embodiment) has been exhausted entirely, maintenance operation for the apparatus is simplified and the cost and time for the maintenance can also be reduced remarkably.

Further, in the present invention, since fabrication is performed throughout the plurality of the discharge tubes (four tubes in this embodiment) under the identical tuning as it is, the number of times of tuning can be reduced relatively compared with the conventional case in which tuning has to be applied on every time when the fabrication performance of individual discharge tube lowers exceeding the allowable range. Thus, entire fabrication efficiency in the local dry etching fabrication can be improved remarkably.

In the present invention, it is described above that the discharge tube to be used is switched by calculating the etching rate during fabrication based on the measurement result of the workpiece after fabrication. In addition to the measurement result of the workpiece after fabrication, the irradiation destination of the electromagnetic wave can be switched by the electromagnetic wave switcher also based on predetermined fabrication parameter, or previously calculated etching rate by the apparatus characteristic or fabrication conditions; predetermined number of workpieces to be fabricated, fabrication time, or fabrication conditions; monitor values of the apparatus having a correlation with the etching rate; or other data or conditions regarding the local dry etching apparatus.

Moreover, in the present invention, while the electromagnetic wave oscillated by the electromagnetic wave oscillator 6 is shown as microwave, it is not restricted to microwave, but also may be well-known electromagnetic waves of short wave lengths in frequency bands used for the plasma excitation, and, for example, a high frequency wave or the like is also applicable. Furthermore, while the electromagnetic wave transmission unit is shown as the waveguide in the present invention, it is also possible to use an electromagnetic wave transmission unit (including cable) in accordance with the frequency band and the output of the electromagnetic wave.

### REFERENCE SIGNS LIST

1 local dry etching apparatus
2 vacuum chamber
31 to 34 discharge tubes
35 to 38 plasma generation portions
41 to 44, 45 wave guides
5 electromagnetic wave switcher
6 electromagnetic wave oscillator
7 workpiece table
8 control device
9 raw material gas supply device
91, 92 cylinders
95 to 98 valve devices
A plasma generation portion
E etching rate
G active species gas
N nozzle
T workpiece table
W workpiece
Wa relatively thick portion

1. A local dry etching apparatus comprising:
a vacuum chamber,
a plurality of discharge tubes each having a nozzle opening in the vacuum chamber at the downstream side for injecting an active species gas converted into plasma,
a single workpiece table which mounts a workpiece thereon and is disposed in the vacuum chamber to the injection destination of the active species gas from the nozzle,
a control device for controlling planar movement of the workpiece table,
a raw material gas supply device for supplying a raw material gas as the raw material for the active species gas to a discharge tube selected from the plurality of the discharge tubes,
a single electromagnetic wave oscillator capable of output adjustment,
plasma generation portions each forming a part of the plurality of the discharge tubes where the raw material gas is converted into plasma to form an active species gas by irradiation of an electromagnetic wave oscillated by the single electromagnetic wave oscillator, and
an electromagnetic wave transmission unit comprising an electromagnetic wave switcher for switching the path of the electromagnetic wave in order to irradiate the electromagnetic wave oscillated by the single electromagnetic wave oscillator to the plasma generation portion of the discharge tube selected from the plurality of the discharge tubes for the supply of the raw material gas.

2. The local dry etching apparatus of claim 1, wherein the raw material gas supply device is switched by a valve device incidental to the local dry etching apparatus so as to supply the gas from a single raw material gas supply source to a discharge tube selected from the plurality of discharge tubes.

3. A local dry etching fabrication method using the local dry etching apparatus of claim 1, the method comprising:
subjecting a workpiece to local dry etching fabrication by the local dry etching apparatus, measuring the unloaded workpiece after fabrication, and calculating an etching rate during fabrication based on the result of the measurement;
fabricating the next workpiece by using the same discharge tube at the identical output as it was when the calculated etching rate is within an allowable range not requiring adjustment of the output of the electromagnetic wave oscillator, or switching the irradiation of the electromagnetic wave by the electromagnetic wave switcher and switching the supply of the raw material gas in order to use another discharge tube not used for the fabrication described above when the etching rate is out of the allowable range; and
further repeating the local dry etching fabrication by adjusting the output of the electromagnetic wave oscillator to a higher output when all of the plurality of the discharge tubes have been used at the identical output of the electromagnetic wave oscillator as it has been; thereby reducing frequency of evacuation accompanied by replacement of the discharge tubes and frequency of tuning.

4. The local dry etching fabrication method of claim 3, wherein the raw material gas supply device is switched by a valve device incidental to the local dry etching apparatus so as to supply a gas from a single raw material gas supply source to a discharge tube selected from the plurality of discharge tubes.
